(19) United States
(12) Patent Application Publication
(10) Pub. No.: US 2024/0404967 A1
(43) Pub. Date: Dec. 5, 2024

(54) MONOLITHICALLY INTEGRATED SEMICONDUCTOR DEVICE STRUCTURE

(71) Applicant: Enkris Semiconductor (Wuxi), Ltd., Wuxi (CN)

(72) Inventor: Guoqiao TAO, Wuxi (CN)

(73) Assignee: Enkris Semiconductor (Wuxi), Ltd., Wuxi (CN)

(21) Appl. No.: 18/607,794

(22) Filed: Mar. 18, 2024

(30) Foreign Application Priority Data
Jun. 1, 2023 (CN) 202310646196.0

(51) Int. Cl. H01L 23/66; H01L 27/06; H01L 29/06; H01L 29/778

(52) U.S. Cl. CPC H01L 23/66; H01L 27/0629; H01L 28/10; H01L 28/40; H01L 29/0607; H01L 29/7786; H01L 2223/6683

(57) ABSTRACT

A monolithically integrated semiconductor device structure includes: a substrate and a transistor; the substrate includes a transistor region; the transistor is positioned above the transistor region comprising at least one first trench and at least one second trench that are arranged in a horizontal direction and extend in a vertical direction; and the first trench is disposed below a drain of the transistor, and the second trench is disposed below a non-drain region of the transistor. In the present disclosure, the first trench and the second trench that are disposed in the substrate of the monolithically integrated semiconductor device structure, which may reduce the equivalent dielectric constant of the substrate and improve the equivalent resistivity, so that the parasitic capacitance and leakage current of the substrate below the transistor are reduced.

### CROSS-REFERENCE TO RELATED APPLICATION

The present disclosure claims priority to Chinese Patent Application No. 202310646196.0,filed on Jun. 1, 2023, which is hereby incorporated by reference in its entirety.

### TECHNICAL FIELD

The present disclosure relates to the field of semiconductor technologies, and in particular, to a monolithically integrated semiconductor device structure.

### BACKGROUND

A monolithic microwave integrated circuit, or MMIC, is an integrated circuit (IC) device operating at a microwave frequency (300 MHz to 300 GHz). These devices typically perform functions such as microwave mixing, power amplification, low noise amplification and high frequency switching. The monolithic microwave integrated circuit has a series of advantages of low circuit loss, low noise, wide frequency band, wide dynamic range, high power, high additional efficiency and the like.

The monolithic microwave integrated circuits typically require a high-resistivity silicon substrate or a high-resistivity SiC substrate to reduce possible eddy current, parasitic capacitance and/or current leakage in the substrate. However, the high-resistivity substrate or the high-resistivity SiC substrate is expensive and easy to break, which would improve the production cost greatly.

### SUMMARY

In view of this, embodiments of the present disclosure provide a monolithically integrated semiconductor device structure to at least solve some of the forgoing technical problems.

According to an aspect of the present disclosure, an embodiment of the present disclosure provides a monolithically integrated semiconductor device structure, including a substrate and a transistor. The substrate includes a transistor region. The transistor is positioned above the transistor region, and the transistor region includes at least one first trench and at least one second trench that are arranged in a horizontal direction and extended in a vertical direction, wherein the first trench is disposed below a drain of the transistor, and the second trench is disposed below a non-drain region of the transistor.

In a first possible implementation, the substrate further comprises a capacitive region, the semiconductor device structure further comprises a capacitor, the capacitor is positioned above the capacitive region comprising the at least one first trench arranged in a horizontal direction and extended in a vertical direction.

In combination with the possible implementations, in another possible implementation, first dielectric is filled in the first trench.

In combination with the possible implementations, in another possible implementation, the first dielectric includes a low-k material.

In combination with the possible implementations, in another possible implementation, the low-k material includes at least one of: an inorganic material, an organic material, a porous material or air.

In combination with the possible implementations, in another possible implementation, second dielectric is filled in the second trench.

In combination with the possible implementations, in another possible implementation, the second dielectric includes an insulating material.

In combination with the possible implementations, in another possible implementation, the insulating material includes at least one of: an oxide material, a nitride material, an organic polymer material, a diamonds or air.

In combination with the possible implementations, in another possible implementation, the substrate is a silicon substrate.

In combination with the possible implementations, in another possible implementation, openings of the first trench and the second trench are disposed on a surface of the substrate facing the transistor, and the first trench and the second trench penetrate through the substrate or do not penetrate through the substrate.

In combination with the possible implementations, in another possible implementation, a depth of the first trench ranges from 15 μm to 80 μm and/or a depth of the second trench ranges from 15 μm to 80 μm.

In combination with the possible implementations, in another possible implementation, a width of the first trench ranges from 0.5 μm to 5 μm, and/or a width of the second trench ranges from 0.5 μm to 5 μm; and the width of the first trench is greater than that of the second trench.

In combination with the possible implementations, in another possible implementation, a projection shape of one or both of the first trench and the second trench on a plane where the substrate is located includes at least one of: a circle, an ellipse, a polygon, a strip or a mesh.

In combination with the possible implementations, in another possible implementation, a cross-sectional area of the first trench and/or the second trench increases gradually or is a constant along a direction from the substrate to the transistor.

In combination with the possible implementations, in another possible implementation, the substrate further includes an inductive region, the semiconductor device structure further includes an inductive element, the inductive element is positioned above the inductive region, and the inductive region comprises at least one the second trench arranged in a horizontal direction and extended in a vertical direction.

In combination with the possible implementations, in another possible implementation, a projection shape of the second trench in the inductive region on a plane where the substrate is located is a star.

In combination with the possible implementations, in another possible implementation, a density of the second trench in the inductive region decreases gradually from a center of the inductive region to an edge of the inductive region.

In combination with the possible implementations, in another possible implementation, the inductive element includes an inductive coil, and an area surrounded by the second trench at an outermost circle of the inductive region is greater than an area surrounded by an outermost contour of the inductive coil.

In combination with the possible implementations, in another possible implementation, the inductive region of the substrate is adjacent to the transistor region.

In combination with the possible implementations, in another possible implementation, the transistor includes a barrier layer, a first dielectric layer and a second dielectric layer that are stacked sequentially; a source, a grid and a drain that are located on the barrier layer, and a grid field plate structure penetrating through the second dielectric layer.

### BRIEF DESCRIPTION OF THE DRAWINGS

FIG. 1 is a schematic structural diagram of a semiconductor device structure according to an embodiment of the present disclosure.

FIG. 2 is a schematic structural diagram of a semiconductor device structure according to an embodiment of the present disclosure.

FIG. 3 is a schematic structural diagram of a semiconductor device structure according to an embodiment of the present disclosure.

FIG. 4 is a schematic structural diagram of a semiconductor device structure according to an embodiment of the present disclosure.

FIG. 5a to FIG. 5e are top views of a first trench/a second trench of a semiconductor device structure according to an embodiment of the present disclosure.

FIG. 6a to FIG. 6b are top views of an inductive region of a semiconductor device structure according to an embodiment of the present disclosure.

FIG. 7 is a top view of an inductive region of a semiconductor device structure according to an embodiment of the present disclosure.

FIG. 8 is a schematic structural diagram of a semiconductor device structure according to an embodiment of the present disclosure.

### DETAILED DESCRIPTION OF THE EMBODIMENTS

The following may provide a clear and complete description of the technical solutions of the present application in conjunction with the accompanying drawings. Apparently, the described embodiments are part of the embodiments of the present application, not all of them. Based on the embodiments of the present application, all other embodiments obtained by a person of ordinary skill in the art without creative efforts fall within the scope of protection of the present application.

To address the technical issues of reduced substrate eddy current and high substrate cost that are difficult to balance in the relative technology of monolithic microwave integrated circuits, the present disclosure provides a monolithically integrated semiconductor device structure including a substrate and a transistor. The substrate includes a transistor region positioned above the transistor region. The transistor region has at least one first trench and at least one second trench that are arranged in a horizontal direction and extended in a vertical direction. The first trench is disposed below a drain of the transistor, and the second trench is disposed below a non-drain region of the transistor. The first trench and the second trench may reduce the equivalent dielectric constant of the substrate and increase the resistivity of the substrate, which may at least reduce a parasitic capacitance and leakage current below the transistor.

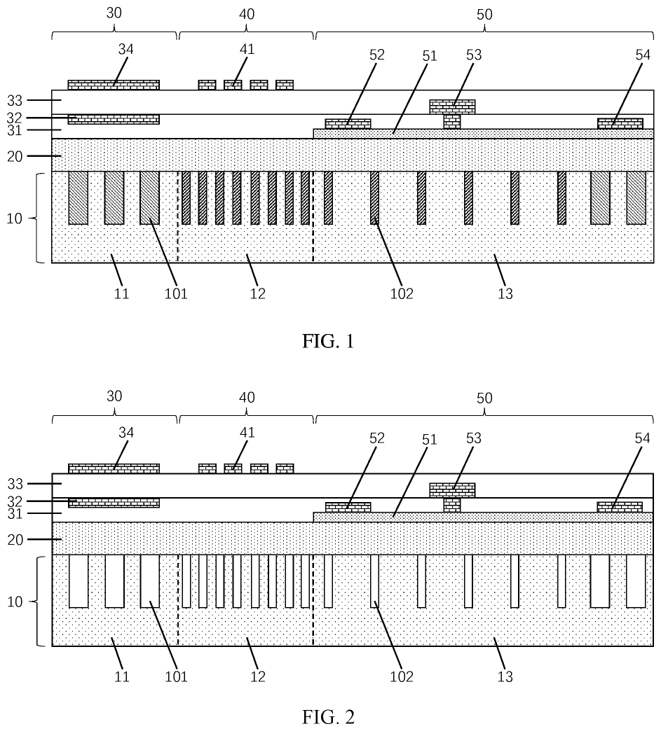

The following further illustrates a monolithically integrated semiconductor device structure mentioned by the present disclosure with reference to FIG. 1 to FIG. 8.

FIG. 1 is a schematic structural diagram of a semiconductor device structure according to an embodiment of the present disclosure. As shown in FIG. 1, a semiconductor device structure includes a substrate 10, a buffer layer 20, a capacitor 30, an inductive element 40 and a transistor 50. The substrate 10 includes a capacitive region 11, an inductive region 12 and a transistor region 13 that are arranged regularly in a horizontal direction. The buffer layer 20 is positioned above the substrate 10. The capacitor 30 is positioned above the buffer layer 20 which is located above the capacitive region 11, and the capacitor 30 includes a first dielectric layer 31, a first electrode 32, a second dielectric layer 33 and a second electrode 34 that are stacked sequentially. The inductive element 40 is positioned above the buffer layer 20 which is located above the inductive region 12. The inductive element 40 includes the first dielectric layer 31, the second dielectric layer 33 and an inductive coil 41, which are stacked sequentially. The transistor 50 is positioned above the buffer layer 20 which is located above the transistor region 13, and the transistor 50 includes a barrier layer 51, the first dielectric layer 31, the second dielectric layer 33, a source 52, a gate 53 and a drain 54, wherein the source 52, the gate 53 and the drain 54 stack on the barrier layer 51 sequentially. The substrate 10 has a first trench 101 and a second trench 102 that are arranged in a horizontal direction and extend in a vertical direction. Specifically, a plurality of the first trenches 101 are disposed in the capacitive region 11, a plurality of the second trenches 102 are disposed in the inductive region 12, and a plurality of first trenches 101 and a plurality of second trenches 102 are disposed in the transistor region 13. Moreover, the plurality of the first trench 101 disposed below the transistor are disposed below a drain 54 of the transistor, and the plurality of the second trench 102 disposed below the transistor are disposed below a non-drain region. The depth of the first trench and the second trench are both less than the thickness of the substrate 10, that is, the first trench and the second trench do not penetrate through the substrate 10 in a depth direction of the substrate 10. The transistor 50 is a high electron mobility transistor.

The first trench 101 is filled with first dielectric, the second trench 102 is filled with second dielectric. The first dielectric includes a low-k material. The low-k material includes at least one of: an inorganic material, an organic material, a porous material or air. The inorganic low-k material includes an amorphous carbon-nitrogen film, a polycrystalline boron-nitrogen film, a fluorosilicate glass, a borosilicate glass (BSG), a phosphor-silicate glass (PSG) and a boro-phospho-silicate glass (BPSG). The organic low-k material includes an organic polymer containing an aryl group or a multi-membered ring. The porous low-k material includes a silsesquioxane (SSQ)-based low-k material, a porous silicon dioxide, a porous SiOCH, a C-doped silicon dioxide, a F-doped porous amorphous carbon, a porous diamond and a porous organic polymer. The second dielectric includes an insulating material. The insulating material includes at least one of: an oxide material, a nitride material, an organic polymer material, a diamond or air. The oxide material includes a silicon oxide. The nitride material includes a silicon nitride oxide. The substrate 10 is a silicon substrate, and the substrate 10 is a non-high resistivity substrate. By manufacturing trenches and filling the dielectric (with better thermal conductivity) in the silicon substrate, an equivalent dielectric constant of the low-resistivity silicon substrate may be reduced thereby increasing the equivalent resistivity of the low-resistivity silicon substrate. Similar to a high-resistivity silicon substrate, the higher equivalent resistivity may reduce the generation of eddy current and parasitic capacitance in the substrate due to the influence of devices above the substrate. In this way, the production cost may be reduced and the problem of high cost of the high-resistivity silicon substrate is solved. The second trench 102 disposed in the inductive region 12 of the substrate 10 may prevent the substrate 10, located below an inductive coil 41, from forming an induced magnetic field due to the magnetic field change, so that the eddy current loss is avoided and the inductive quality factor is greatly improved. The first trench 101 disposed corresponding to a region of the drain 54 in the transistor region 13 may reduce a parasitic capacitance of the region. The second trench 102 disposed corresponding to a region of a non-drain may reduce a current leakage of the substrate 10 below the transistor 50 and improve the efficiency and the performance of devices.

FIG. 2 is a schematic structural diagram of a semiconductor device structure according to an embodiment of the present disclosure. In the embodiment, the semiconductor device structure is basically the same as the semiconductor device structure shown in FIG. 1, the difference is that there is no dielectric filled in the first trench 101 and the second trench 102, and they are disposed to be in a vacuum state. The substrate with the vacuum trench may also have a higher equivalent resistivity than that of the substrate material, thereby reducing the parasitic capacitance in the substrate 10 beneath the capacitor element or other elements, and reducing the eddy current below the inductive element.

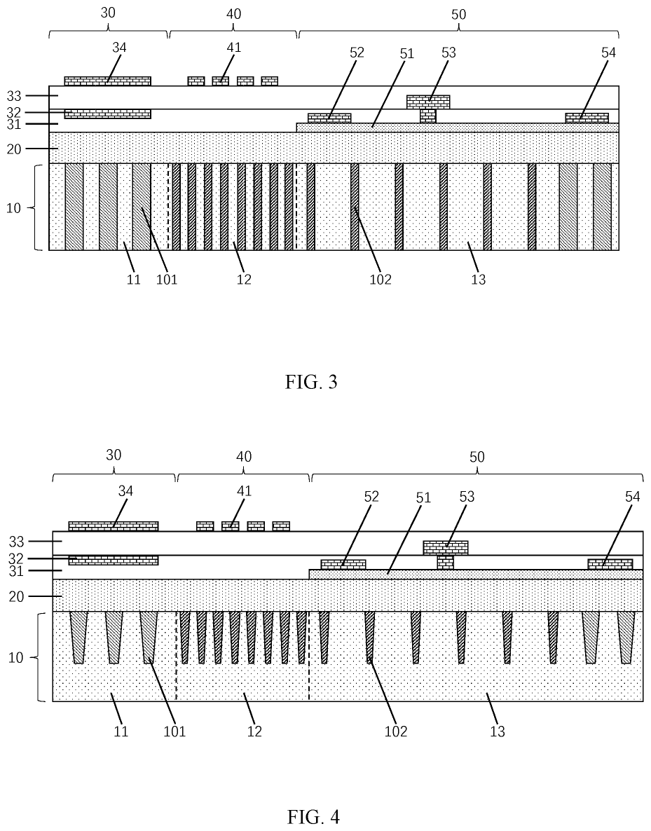

FIG. 3 is a schematic structural diagram of a semiconductor device structure according to an embodiment of the present disclosure. In the embodiment, the semiconductor device structure is basically the same as the semiconductor device structure shown in FIG. 1, the difference is that the first trench 101 and the second trench 102 penetrate through the substrate 10 in a depth direction. Openings of the first trench 101 and the second trench 102 are disposed on the surface (close to the buffer layer 20) of the substrate 10. In some alternative embodiments, the first trench and the second trench 102 may not penetrate through the substrate 10 (as shown in FIG.1).

FIG. 4 is a schematic structural diagram of a semiconductor device structure according to an embodiment of the present disclosure. In the embodiment, the semiconductor device structure is basically the same as the semiconductor device structure shown in FIG. 1, the difference is that each cross-sectional area of the first trench 101 and the second trench 102 increases gradually in the direction from the substrate 10 to the buffer layer 20. The depth of the first trench 101 and the second trench 102 ranges from 15 μm to 80 μm. A width of the first trench 101 and the second trench 102 ranges from 0.5 μm to 5 μm. By designing different sizes of the first trench 101 and the second trench 102, the equivalent dielectric constant and the equivalent resistivity of the substrate 10 may be adjusted. The width of the first trench 101 is greater than that of the second trench 102. The first trench is wider, which may better reduce the equivalent dielectric constant of the substrate 10, thereby reducing the parasitic capacitance in the substrate 10. The second trench 102 has a smaller width, which is sufficient to cut off eddy current or induced current.

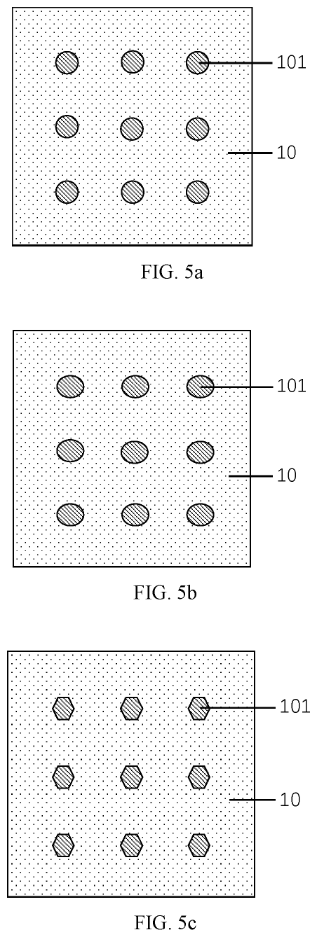

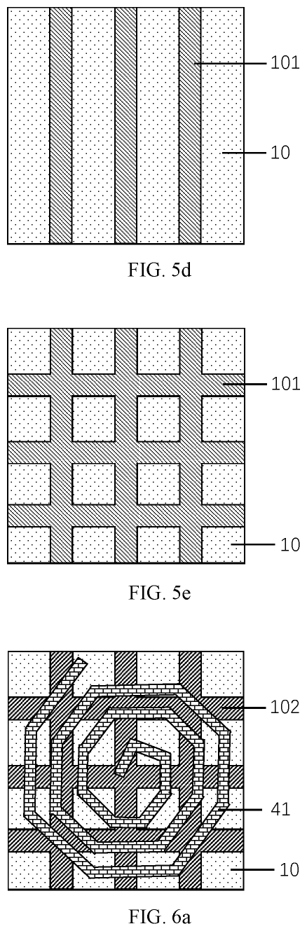

FIG. 5a to FIG. 5e are top views of a first trench/a second trench in a semiconductor device structure according to an embodiment of the present disclosure. The projection shape of the first trench 101 and the second trench 102 on a plane where the substrate 10 is located includes at least one of: a circle (as shown in FIG. 5a), an ellipse (as shown in FIG. 5b), a polygon (as shown in FIG. 5c), a strip (as shown in FIG. 5d) or a mesh (as shown in FIG. 5e). The projection shapes of the trenches are not specifically limited in the embodiments of the present disclosure.

As shown in FIG. 1, in some embodiments, the number of the first trench 101 of the capacitive region 11 is multiple, and/or, the number of the second trench 102 of the inductive region 12 is multiple, and/or, the number of the first trench 101 and the second trench 102 in the transistor region 13 is multiple, and/or, the number of the first trench 101 of the transistor region 13 below the drain 54 is multiple, and/or, the number of the second trench 102 of the transistor region 13 below the non-drain 54 region is multiple. In some alternative embodiments, the number of the first trench 101 of the capacitive region 11 is one, and/or, the number of the second trench 102 of the inductive region 12 is one, and/or, the number of the first trench 101 and the second trench 102 in the transistor region 13 is one, and/or, the number of the first trench 101 of the transistor region 13 below the drain 54 is one, and/or, the number of the second trench 102 of the transistor region 13 below the non-drain 54 is one. The first trench 101 disposed in the capacitive region 11 and the first trench 101 disposed in the transistor region 13 which is disposed below the drain 54 may reduce the equivalent dielectric constant of the capacitive region 11 and the transistor region 13 disposed below the drain 42, thereby reducing the parasitic capacitance of the substrate disposed below the capacitor 30 and the drain 54 of the transistor 50. The second trench 102 disposed in the inductive region 12 may prevent the substrate 10, located below an inductive coil 41, from forming an induced magnetic field due to the magnetic field change, so that the eddy current loss is reduced and the inductive quality factor is greatly improved. The second trench 102 disposed in the transistor region 13 below the non-drain 54 may reduce a current leakage of the substrate 10 below the transistor 50.

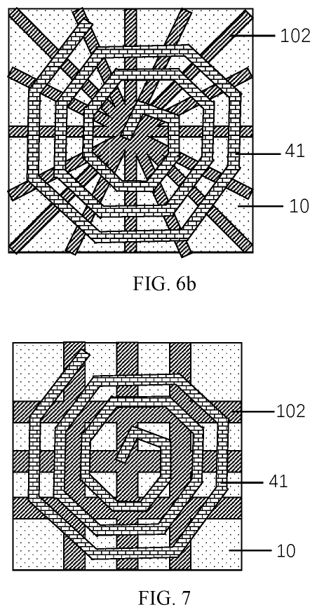

FIG. 6a to FIG. 6b are top views of an inductive region in a semiconductor device structure according to some embodiments of the present disclosure. The projection of the second trench 102 in the inductive region 12 on the plane where the substrate 10 is located is in a mesh shape (as shown in FIG. 6a) or a star shape/radiant shape (as shown in FIG. 6b). The shape of the eddy current that may be generated in the inductive region 12 is the same as that of the inductive coil 41, by designing the second trench 102 with a star shape or a mesh shape, the eddy current path may be cut off and the eddy current loss may be reduced, thereby improving the inductance quality factor.

In an embodiment, as shown in FIG. 6a, an area surrounded by the second trench 102 at an outermost circle of an inductive region 12 is greater than an area surrounded by an outermost contour of the inductive coil 41, thus better cutting off the eddy current lines generated by the inductive coil 41.

FIG. 7 is a top view of an inductive region in a semiconductor device structure according to an embodiment of the present disclosure. As shown in FIG. 7, a density of the second trench 102 of the inductive region 12 is decreased gradually from the center of the inductive region 12 to an edge. The magnetic field lines generated by the inductive coil 41 is closed, so the magnetic field lines all pass through the inner diameter of the inductive coil, which causes the magnetic field density in the inner diameter of the coil is highest. Therefore, the density of the second trench 102 is designed to be greater at the center of the inductive region 12 and smaller at the edge of the inductive region 12.

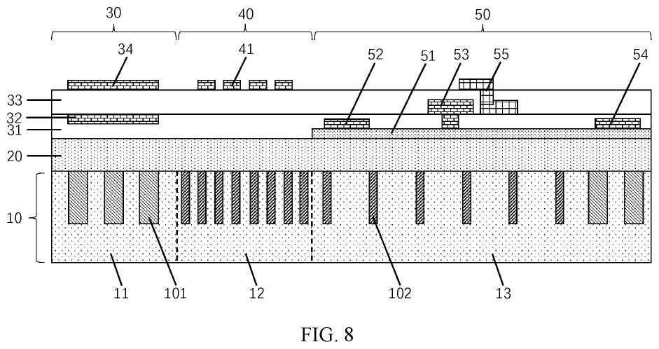

FIG. 8 is a schematic structural diagram of a semiconductor device structure according to an embodiment of the present disclosure. As shown in FIG.8, the transistor 50 further includes a gate field plate structure 55 penetrating through the second dielectric layer 33. The gate field plate structure 55 is designed to relieve the electric field aggregation effect at the edge of the gate 53, so as to reduce the original electric field peak close to the gate 53, reduce the probability of failure degradation of the transistor 50 at a high electric field stress, and improve the reliability of the device.

The present disclosure provides a monolithically integrated semiconductor device structure, including: a substrate, a buffer layer, a capacitor, an inductive element and a high electron mobility transistor. The substrate includes a capacitive region, an inductive region and a transistor region that are arranged regularly in a horizontal direction. The buffer layer is positioned above the substrate. The capacitor is positioned above the buffer layer above the capacitive region. The inductive element is positioned above the buffer layer above the inductive region. The high electron mobility transistor is positioned above the buffer layer above the transistor region. The substrate has a first trench and a second trench that are arranged in a horizontal direction at intervals.

In the present disclosure, the first trench is disposed in the substrate of a monolithically integrated semiconductor device structure, so that the equivalent dielectric constant of the substrate may be reduced, thereby reducing a parasitic capacitance of the substrate disposed below the capacitor and the substrate disposed below the drain of the high electron mobility transistor. The second trench is disposed in the substrate, which on one hand may prevent the substrate, located below an inductive coil, from forming an induced magnetic field due to the magnetic field change, so that an eddy current loss is reduced and the inductive quality factor is greatly improved; on the other hand, the second trench disposed in the substrate may reduce a current leakage of the substrate below the high electron mobility transistor, and improve the efficiency and performance of the devices.

The substrate with the first trench and/or the second trench in the present disclosure may replace common high resistivity substrate, which may reduce the eddy current, reduce the parasitic capacitance, and reduce the production cost.

It should be understood that the terms “comprising” and variations thereof used in the present disclosure are open ended, that is, “including but not limited to”. The term “one embodiment” means “at least one embodiment”; and the term “another embodiment” means “at least one further embodiment”. In this specification, the schematic representation of the above terms does not necessarily refer to the same embodiment or example. Furthermore, the particular features, structures, materials, or characteristics described may be combined in any suitable manner in any one or more embodiments or examples. In addition, in the case of no contradiction, a person skilled in the art may combine and combine different embodiments or examples described in this specification and features of different embodiments or examples.

The above are only preferred embodiments of the present application, and are not intended to limit the protection scope of the present application. Any modification, equivalent replacement, improvement and the like made within the spirit and principle of this application shall be included within the protection scope of this application.

What is claimed is:

1. A monolithically integrated semiconductor device structure, comprising:
a substrate comprising a transistor region; and
a transistor positioned above the transistor region comprising at least one first trench and at least one second trench that are arranged in a horizontal direction and extend in a vertical direction,
wherein the first trench is disposed below a drain of the transistor, and the second trench is disposed below a non-drain region of the transistor.

2. The monolithically integrated semiconductor device structure according to claim 1, wherein the substrate further comprises a capacitive region, the semiconductor device structure further comprises a capacitor, and the capacitor is positioned above the capacitive region; and the capacitive region comprises the at least one first trench arranged in the horizontal direction and extend in the vertical direction.

3. The monolithically integrated semiconductor device structure according to claim 1, wherein first dielectric is filled in the first trench.

4. The monolithically integrated semiconductor device structure according to claim 3, wherein the first dielectric comprises a low-k material.

5. The monolithically integrated semiconductor device structure according to claim 4, wherein the low-k material comprises at least one of: an inorganic material, an organic material, a porous material or air.

6. The monolithically integrated semiconductor device structure according to claim 1, wherein second dielectric is filled in the second trench.

7. The monolithically integrated semiconductor device structure according to claim 6, wherein the second dielectric comprises an insulating material.

8. The monolithically integrated semiconductor device structure according to claim 7, wherein the insulating material comprises at least one of: an oxide material, a nitride material, an organic polymer material, a diamond or air.

9. The monolithically integrated semiconductor device structure according to claim 1, wherein the substrate is a silicon substrate.

10. The monolithically integrated semiconductor device structure according to claim 1, wherein openings of the first trench and the second trench are disposed on a surface, facing the transistor, of the substrate, and the first trench and the second trench penetrate through the substrate or do not penetrate through the substrate.

11. The monolithically integrated semiconductor device structure according to claim 1, wherein a depth of the first trench ranges from 15 μm to 80 μm and/or a depth of the second trench ranges from 15 μm to 80 μm.

12. The monolithically integrated semiconductor device structure according to claim 1, wherein
a width of the first trench ranges from 0.5 μm to 5 μm, and/or a width of the second trench ranges from 0.5 μm to 5 μm, and
the width of the first trench is greater than the width of the second trench.

13. The monolithically integrated semiconductor device structure according to claim 1, wherein a projection shape of one or both of the first trench and the second trench on a plane where the substrate is located comprises at least one of: a circle, an ellipse, a polygon, a strip or a mesh.

14. The monolithically integrated semiconductor device structure according to claim 1, wherein a cross-sectional area of the first trench and/or the second trench increases gradually or is a constant along a direction from the substrate to the transistor.

15. The monolithically integrated semiconductor device structure according to claim 1, wherein the substrate further comprises an inductive region, the semiconductor device structure further comprises an inductive element, the inductive element is positioned above the inductive region, and the inductive region comprises at least one second trench arranged in a horizontal direction and extended in a vertical direction.

16. The monolithically integrated semiconductor device structure according to claim 15, wherein a projection shape of the second trench in the inductive region on a plane where the substrate is located is a star.

17. The monolithically integrated semiconductor device structure according to claim 15, wherein a density of the second trench in the inductive region decreases gradually from a center of the inductive region to an edge of the inductive region.

18. The monolithically integrated semiconductor device structure according to claim 15, wherein the inductive element comprises an inductive coil, and an area surrounded by the second trench at an outermost circle of the inductive region is greater than an area surrounded by an outermost contour of the inductive coil.

19. The monolithically integrated semiconductor device structure according to claim 15, wherein the inductive region of the substrate is adjacent to the transistor region.

20. The monolithically integrated semiconductor device structure according to claim 1, wherein the transistor comprises a barrier layer, a first dielectric layer and a second dielectric layer that are stacked sequentially; a source, a gate and a drain that are located on the barrier layer; and a gate field plate structure penetrating through the second dielectric layer.
